(19) United States
(12) Patent Application Publication
(10) Pub. No.: US 2009/0059535 A1
(43) Pub. Date: Mar. 5, 2009

(54) Cooling device coated with carbon nanotube and of manufacturing the same

(76) Inventors: Yong-Hyup Kim, Gyeonggi-do (KR); Ho-Young Lee, Seoul (KR); Seung-Min Lee, Seoul (KR); Woo-Yong Sung, Seoul (KR); Tae-Jun Kang, Seoul (KR); Wal-Jun Kim, Seoul (KR); Jang-Won Yoon, Seoul (KR); Sun-Chang Yeon, Seoul (KR)

Correspondence Address: THE NATH LAW GROUP, 112 South West Street, Alexandria, VA, 22314, US

(21) Appl. No.: 11/988,173

(22) PCT Filed: Aug. 18, 2005
(86) PCT No.: PCT/KR2005/002715

§ 371 Date: Apr. 16, 2008

(30) Foreign Application Priority Data
Jul. 5, 2005 (KR) 10-2005-0060057

(51) Int. Cl. H05K 7/20; B05D 1/18

(52) U.S. Cl. 361/710; 361/704; 427/435; 427/372.2; 977/742; 977/949

(57) ABSTRACT

Provided are a cooling device coated with carbon nanotubes and method of manufacturing the same. Carbon nanotubes are dispersively coated on a surface of the cooling device that radiates generated by a predetermined apparatus or component through thermal exchange. Thus, a carbon nanotube structure is formed so that the cooling device can improve in a thermal radiation characteristic and become small-sized. As a result, electronic devices can be downscaled and heat generated by a highly integrated electronic circuit chip can be effectively radiated, thus increasing lifetime and performance of an operating circuit.

### TECHNICAL FIELD

The present invention relates to a cooling device and method of manufacturing the same, and more particularly, to a cooling device in which a carbon nanotube structure is formed using a dip coating process and method of manufacturing the same.

### BACKGROUND ART

As is well known, a high power amplifier (APM) and linear power amplifier (LPA) for a mobile communication relay, a central processing unit (CPU) for a personal computer (PC), a multiple processing unit (MPU) for a server-level workstation, and a power amplifier unit (PAU) for a relay base station are electronic components that generate a lot of heat. When the electronic components operate under breaking load, their surface temperatures are elevated and they are overheated due to generated heat. Thus, there is a strong possibility of causing malfunction and breakage of the components.

In order to prevent the malfunction and breakage of the components, a device of radiating heat from electronic apparatuses was proposed. Generally, a fin heat sink and a heat pipe are used as representatives of the radiation device. The fin heat sink serves to radiate heat generated by a heat source using a cooling fin. Also, the heat pipe serves to radiate heat generated by a heat source by moving the heat through a capillary structure.

FIG. 1 is a perspective view of a conventional CPU cooling apparatus for a fin heat sink.

Referring to FIG. 1, a CPU 50 is mounted on a main board 10, and a cooling device 30 is disposed on the CPU 50. A bottom plate 31 of the cooling device 30 is in contact with the CPU 50, and a plurality of cooling fins 32 vertically protrude from a top surface of the bottom plate 31.

A cooling fan 20 is disposed on the cooling device 30 and sends air to the cooling device 30 that is adhered to a top surface of the CPU 50 so that the CPU 50 is cooled off.

Thermal energy generated by the CPU 50 is transmitted to the cooling device 30 that is in contact with the CPU 50. Then, the cooling device 30 is cooled by air, which is sent by the cooling fan 20 between the bottom plate 31 and the cooling fins 32 of the cooling device 30. Thus, the thermal energy transmitted to the cooling device 30 is reduced.

FIG. 2 is a cross sectional view of a conventional heat pipe. The heat pipe is very advantageous for transmitting a large amount of heat, causing no noise, and requiring no external power.

Referring to FIG. 2, the heat pipe includes a liquid coolant 110, which serves to transmit heat using phase change in a sealed pipe 120. Specifically, when a heat absorber 100 absorbs heat generated by a heating element, such as a CPU, the liquid coolant 110 evaporates and reaches a condenser 130 corresponding to an upper portion of the pipe 120, so that heat is radiated. Then, the evaporated coolant is liquefied again and returns downward to the liquid coolant 110 along an inner wall of the pipe 120. The boiling point and condensing point of the liquid coolant 110 are determined by physical properties of liquid and inner pressure of the pipe 120.

### DISCLOSURE OF INVENTION

### Technical Problem

The cooling of an electronic component using the above-described fin heat sink or heat pipe involves a process of radiating heat using cooling fins.

However, even if the above-described cooling device or heat pipe, which is used for a conventional computer cooling apparatus, absorbs a large amount of heat, the number of cooling fins (i.e., heat radiation area or heat transmission area) is restricted to reduce exothermic energy, thus dropping heat radiation efficiency. As a result, exothermic energy cannot be sufficiently radiated.

In order to solve this problem, large-sized cooling fins should be formed. However, this will be costly and make it difficult to scale down the computer cooling apparatus. For this reason, there is no sufficient cooling space for a small-sized and high-integrated electronic device.

Further, in recent years, as the integration density of electronic circuit chips increases, there is a growing tendency to downscale electronic devices. Therefore, developing a small-sized cooling device with high heat exchange efficiency and materials therefor is being an urgent need.

### Technical Solution

The present invention provides a cooling device, which maximizes the surface area of a heat absorber for heat radiation and improves heat transmission efficiency, and method of manufacturing the same.

According to an aspect of the present invention, a carbon nanotube structure is formed on a surface of a cooling fin of a cooling device that radiates heat generated by a predetermined apparatus or component using thermal exchange. A method of manufacturing the cooling device with the carbon nanotube structure includes forming the cooling device having a plurality of cooling fins. The cooling device is dipped in a bath containing a solvent with dispersed carbon nanotubes. After that, a wetting layer is formed on a surface of each of the cooling fins by taking out the cooling device at constant speed. Then, the wetting layer is dried to absorb the carbon nanotubes on the surface of each of the cooling fins.

### Advantageous Effects

The present invention can maximize thermal exchange efficiency by forming a carbon nanotube structure on a cooling device.

Also, the cooling device can become small-sized by improving the thermal exchange efficiency. Thus, electronic devices can be downscaled, and heat generated by a highly integrated electronic circuit chip can be effectively radiated. Consequently, an operating circuit can improve in lifetime and performance.

### BRIEF DESCRIPTION OF THE DRAWINGS

FIG. 1 is a perspective view of a conventional CPU cooling apparatus for a fin heat sink;

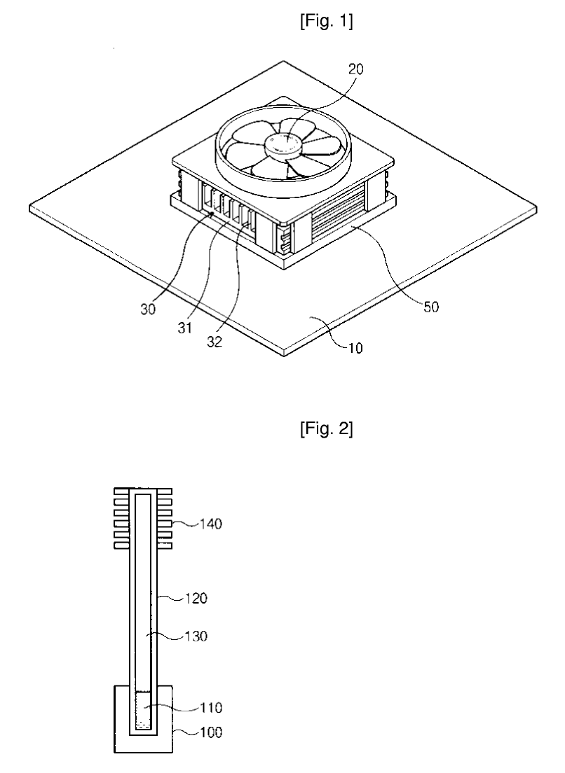

FIG. 2 is a cross sectional view of a conventional heat pipe;

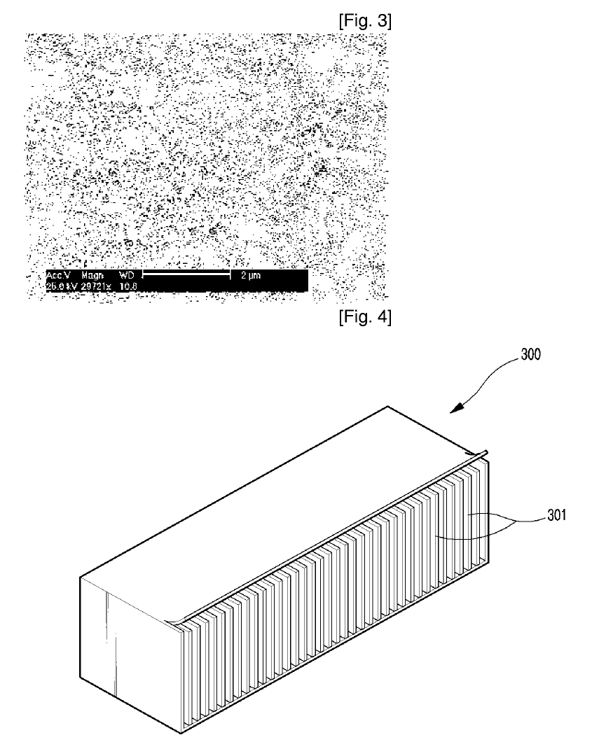

FIG. 3 is a photograph of a cooling fin on which carbon nanotubes are absorbed according to an exemplary embodiment of the present invention; and

FIGS. 4 through 7 are cross sectional views illustrating a method of coating carbon nanotubes on a cooling fin according to an exemplary embodiment of the present invention.

### BEST MODE FOR CARRYING OUT THE INVENTION

The present invention will now be described more fully hereinafter with reference to the accompanying drawings, in which exemplary embodiments of the invention are shown. In the drawings, the forms and thicknesses of layers may be exaggerated for clarity, and the same reference numerals are used to denote the same elements throughout the drawings.

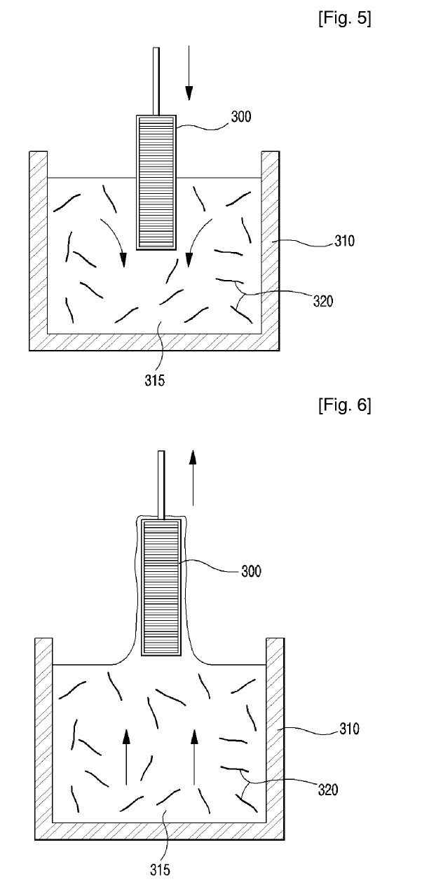

FIG. 3 is a photograph of a surface of a cooling fin to which carbon nanotubes are absorbed according to an exemplary embodiment of the present invention.

FIG. 3 illustrates the surface of the cooling fin after a cooling device including a plurality of cooling fins is formed and a dip coating process is performed on the cooling device. In one embodiment, since carbon nanotubes are formed on the surface of the cooling fin, the cooling fin can increase a contact portion for thermal exchange by several hundred times to several thousand times as compared with a conventional cooling fin having a plane structure. Also, the carbon nanotubes, which have thermal conductivity of 1,800 to 6,000 W/mK, are far more highly thermal conductive than copper (Cu) having a good thermal conductivity of 401 W/mK.

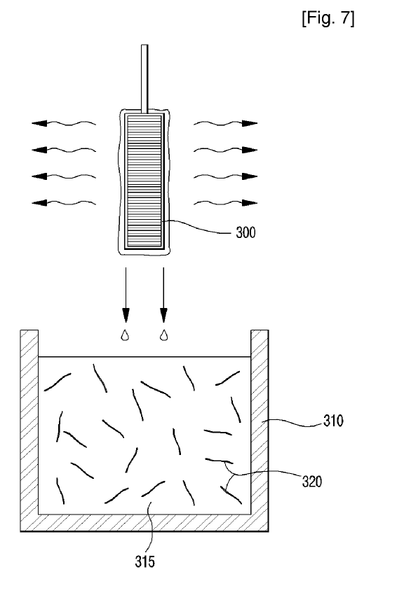

FIGS. 4 through 7 are cross sectional views illustrating a method of coating carbon nanotubes on a cooling fin according to an exemplary embodiment of the present invention.

Referring to FIG. 4, a cooling device 300 including a plurality of cooling fins 301 is assembled. The cooling fins 301 may be formed of Cu.

Referring to FIG. 5, carbon nanotubes 320 are uniformly dispersed in a solvent 315 contained in a bath 310. In the present invention, the carbon nanotubes 320 are, but not limited to, carbon nanotubes having a high aspect ratio of 10 to 10,000 and a high degree of purity of 95% or higher. In the present embodiment, each of the carbon nanotubes 320 had a diameter of 10 to 15 nm and a length of 10 to 20 μm. The dispersion solvent 315, which serves to separate bundles of carbon nanotubes from one another, may be, but not limited to, a solvent that can functionalize carbon nanotubes and has a low evaporation point. For example, the dispersion solvent 315 may be formed of 1,2-dichlorobenzene, isopropyl alcohol (IPA), acetone, methanol, or ethanol. In the present embodiment, dichlorobenzene was used as the dispersion solvent 315. The carbon nanotubes 320 were properly mixed with the solvent 315 and dispersed in the solvent 315 using ultrasonification. The ultrasonification is applicable when no damage is inflicted on the carbon nanotubes 320. In general, the ultrasonification may be performed at an intensity of 40 to 60 KHz for about 1 hour.

Since non-refined carbon nanotubes 320 contain an amorphous catalyst, a metal catalyst, and carbon nanoparticles, before the carbon nanotubes 320 are dispersed in the solvent 315, a pre-processing process is needed. Specifically, impurities are removed and the carbon nanotubes 320 are annealed. Initially, a gas-phase oxidation process or liquid-phase oxidation process is carried out to remove amorphous carbon or carbon nanoparticles from carbon nanotube powder. In a typical gas-phase oxidation process, the carbon nanotube powder is oxidized using a furnace in an air atmosphere for about 1 hour at a temperature of about 470 to 750° C. Also, in a liquid-phase oxidation process, the carbon nanotubes 320 are put in hydrogen peroxide and heated for 12 hours at a temperature of 100° C. As a result, refined carbon nanotubes can be separated from hydrogen peroxide through a gas cavity filter having a size of 0.5 to 1 μm. To remove a metal catalyst used for synthesis of carbon nanotubes, the carbon nanotubes are put in a nitric acid (HNO₃) solution of about 10 g/liter and heated for 1 hour at a temperature of 50° C. Thereafter, in order to cut the refined carbon nanotubes into desired sizes, the refined carbon nanotubes are put in a solution in which H₂SO₄ and HNO₃ are mixed in a ratio of about 3:1 and then heated at a temperature of 70° C. In this case, the length of the carbon nanotubes 320 is determined by heating time. For instance, when the carbon nanotubes 320 were heated for 10 hours, they had a length of about 2 to 5 μm, and when the carbon nanotubes 320 were heated for 20 hours, they had a length of 0.5 to 1.0 μm. Finally, the carbon nanotubes 320 are annealed in a furnace in vacuum or in an air atmosphere at a temperature of 80° C. for 30 minutes, so that functional groups are removed from the carbon nanotubes 320 using acid treatment and re-crystallizing of the carbon nanotubes 320 is decomposed.

After taking the refined carbon nanotubes 320 in the solvent 315, the carbon nanotubes 320 are dispersed in the solvent 315 by conducting ultrasonification for about 1 hour. A small amount of dispersant may be used to effectively disperse the carbon nanotubes 320 if required.

The assembled cooling device 300 is slowly dipped in the solvent 315 in which the carbon nanotubes 320 are dispersed. At first, the carbon nanotubes 320 do not spread to the cooling device 300.

Referring to FIG. 6, the cooling device 300 is slowly taken from the solvent 315 contained in the bath 310 at a constant speed of about 1 to 10 cm/min and at a regular angle of about 10 to 90°. Thus, a wetting layer containing the carbon nanotubes 320 is formed on the cooling device 300.

Referring to FIG. 7, the wetting layer is dried, thus the carbon nanotubes 320 are absorbed on a surface of the cooling fin (301 of FIG. 4). The wetting layer is dried at a temperature of about 80 to 95° C. so that the solvent 315 evaporates rapidly. The drying process may be performed in vacuum to prevent absorption of contaminants contained in air.

In the above-described process, the process of dipping the cooling device 300 in the solvent 315, forming the wetting layer, and drying the wetting layer are repetitively performed about 1 to 40 times, thus carbon nanotubes are appropriately absorbed on the cooling fin.

As described above, it can be explained that the cooling fin is coated with the carbon nanotubes using absorption as driving force. Specifically, the absorbed carbon nanotubes are strongly combined with the cooling fin through Van der Waals force, static electricity, and hydrogen bond. The coated carbon nanotubes are not self-aligned but formless.

When an appropriate number of carbon nanotubes are coated on the cooling device, a cooling effect can be greatly enhanced. However, when the carbon nanotubes are nonuniformly coated and form masses to a serious extent, the cooling effect may be degraded. Accordingly, it is important to coat the cooling device with an appropriate number of carbon nanotubes.

By coating the cooling fin with the carbon nanotubes, surface area greatly increases, thus elevating heat radiation efficiency. In particular, as electronic components are scaled down, cooling devices can effectively improve in a heat radiation characteristic.

According to the present invention as described above, the cooling device increases a surface area by several hundred times to several thousand times as compared with a conventional cooling device. Thus, heat generated by a heating element, such as an electronic device, is absorbed in the cooling device and discharged to air through a carbon nanotube structure formed in an interface of air where most of thermal exchange occurs. In this case, since the carbon nanotube structure has very high thermal conductivity and very large surface area, the generated heat is discharged rapidly to air.

The cooling device coated with carbon nanotubes according to the present invention can be also applied to a device that radiates heat through compression and condensation, for example, an air conditioner and a machine, and not limited to a cooling apparatus (a CPU cooler, a graphic card cooler, a cooling fin, a heat pipe cooler) for a computer including a portable computer.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

### INDUSTRIAL APPLICABILITY

The present invention can maximize thermal exchange efficiency by forming a carbon nanotube structure on a cooling device.

Also, the cooling device can become small-sized by improving the thermal exchange efficiency. Thus, electronic devices can be downscaled, and heat generated by a highly integrated electronic circuit chip can be effectively radiated. Consequently, an operating circuit can improve in lifetime and performance.

1. A method of manufacturing a cooling device comprising:
forming the cooling device including a plurality of cooling fins;
dipping the cooling device in a bath containing a solvent with dispersed carbon nanotubes;
forming a wetting layer on a surface of each of the cooling fins by taking out the cooling device at constant speed; and
drying the wetting layer to absorb the carbon nanotubes on the surface of each of the cooling fins.

2. The method according to claim 1, wherein drying the wetting layer is performed at a temperature of about 80 to 95° C., and dipping the cooling device, forming the wetting layer, and drying the wetting layer are repetitively performed 1 to 40 times.

3. The method according to claim 1, wherein the solvent is formed of at least one selected from the group consisting of 1,2-dichlorobenzene, isopropyl alcohol (IPA), acetone, methanol, and ethanol.

4. The method according to claim 1, wherein each of the carbon nanotubes has a diameter of 10 to 15 nm and a length of 0.5 to 20 μm.

5. A cooling device including a plurality of cooling fins, each cooling fin having a surface to which carbon nanotubes are absorbed, the cooling device formed by the method according to claim 1.

6. A cooling device including a plurality of cooling fins, each cooling fin having a surface to which carbon nanotubes are absorbed, the cooling device formed by the method according to claim 2.

7. A cooling device including a plurality of cooling fins, each cooling fin having a surface to which carbon nanotubes are absorbed, the cooling device formed by the method according to claim 3.

8. A cooling device including a plurality of cooling fins, each cooling fin having a surface to which carbon nanotubes are absorbed, the cooling device formed by the method according to claim 4.
